(19) United States
(12) Patent Application Publication
(10) Pub. No.: US 2024/0360549 A1
(43) Pub. Date: Oct. 31, 2024

(54) LOW-TEMPERATURE DEPOSITION PROCESSES TO FORM MOLYBDENUM-BASED MATERIALS WITH IMPROVED RESISTIVITY

(71) Applicant: Applied Materials, Inc., Santa Clara, CA (US)

(72) Inventors: Feng Q. Liu, San Jose, CA (US); Byunghoon Yoon, Sunnyvale, CA (US); Joung-Joo Lee, San Jose, CA (US); Avgerinos V. Gelatos, Scotts Valley, CA (US); Mark J. Saly, Morgan Hill, CA (US)

(21) Appl. No.: 18/140,179

(22) Filed: Apr. 27, 2023

(51) Int. Cl. C23C 16/34; C23C 16/455; H01L 21/768; H01L 23/532

(52) U.S. Cl. CPC C23C 16/34; C23C 16/45527; H01L 21/76844; H01L 23/53209; H01L 23/53238; H01L 23/53266; H01L 23/5226

(57) ABSTRACT

A method includes performing a reactant step of a deposition cycle of a deposition process to form a molybdenum (Mo)-based material, performing a Mo precursor step of the deposition cycle, and performing a treatment step of the deposition cycle. Performing the reactant step includes introducing a reactant, performing the Mo precursor step includes introducing a Mo precursor, and performing the treatment step includes introducing a treatment gas. The deposition process is performed at a temperature that is less than or equal to about 450° C.

### TECHNICAL FIELD

Embodiments of the present disclosure generally relate to electronic device fabrication. Particularly, embodiments of the present disclosure relate to low-temperature deposition processes to form molybdenum (Mo)-based materials with improved resistivity.

### BACKGROUND

An electronic device manufacturing apparatus can include multiple chambers, such as process chambers and load lock chambers. Such an electronic device manufacturing apparatus can employ a robot apparatus in transfer chamber that is configured to transport substrates between the multiple chambers. In some instances, multiple substrates are transferred together. Process chambers may be used in an electronic device manufacturing apparatus to perform one or more processes on substrates, such as deposition processes and etch processes. For many processes gasses are flowed into the process chamber.

### SUMMARY

In accordance with an embodiment, a method is provided. The method includes performing a reactant step of a deposition cycle of a deposition process to form a molybdenum (Mo)-based material, performing a Mo precursor step of the deposition cycle, and performing a treatment step of the deposition cycle. Performing the reactant step includes introducing a reactant, performing the Mo precursor step includes introducing a Mo precursor, and performing the treatment step includes introducing a treatment gas. The deposition process is performed at a temperature that is less than or equal to about 450° C.

In accordance with an embodiment, a device is provided. The system includes a trench and a liner including a Mo-based material formed along the trench. The Mo-based material has a resistivity less than or equal to about 200 microohm-centimeters (μΩ·cm).

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIGS. 1A-1E are cross-sectional views illustrating an example method of fabricating an electronic device using a low-temperature molybdenum (Mo)-based material deposition process, in accordance with some embodiments.

FIG. 2 is a flowchart of an example method of fabricating an electronic device using a low-temperature process to a form molybdenum (Mo)-based material with improved resistivity, in accordance with some embodiments.

FIG. 3 is a diagram of an example method of low-temperature molybdenum (Mo)-based material deposition, in accordance with some embodiments.

FIG. 4 is a diagram of an example method of low-temperature molybdenum (Mo)-based material deposition, in accordance with some embodiments.

FIG. 5 is a diagram of a top-down view of a multi-chamber processing platform system that can be used to implement a method of low-temperature molybdenum (Mo)-based material deposition, in accordance with some embodiments.

### DETAILED DESCRIPTION

Embodiments described herein relate to low-temperature deposition processes to form molybdenum (Mo)-based materials with improved resistivity. As semiconductor technology nodes continue to shrink in size (e.g., less than or equal to about 3 nanometer (nm) nodes), electronic performance of conductive material becomes even more important for advanced chip performance. To further improve conductivity, the resistivity contribution of liners can be considered. Some liners are formed from materials that have relatively high resistance, such as tungsten-based liners. Examples of tungsten-based liners include tungsten nitride.

Molybdenum (Mo)-based materials can exhibit lower resistivity as compared to other materials, such as tungsten nitride. However, Mo has a strong bonding energy with elements such as carbon (C), nitrogen (N) and oxygen (O). Therefore, it can be difficult to achieve suitable deposition of Mo-based materials from organometallic precursors. One example of a Mo-based material is molybdenum nitride (MoN). Some processes for depositing MoN materials include employing (Mo(NR)₂(NR₂))₂ precursors that result in higher resistivity films, which can be less desirable for more advanced technology nodes. For example, a MoN material deposited using such a precursor can be formed to have a thickness of about 10 nm and a corresponding resistivity that is greater than about 1000 microohm-centimeters (μΩ·cm). Additionally, some Mo-based material deposition processes can employ Mo-based halides that can damage underlying conductive layers (e.g., metal layers) and can be performed at high temperatures (e.g., greater than about 400° C.) that further deter implementation of Mo-based liners with respect to advanced technology nodes.

To address these and other drawbacks, embodiments described herein provide for low-temperature deposition processes to form Mo-based materials with improved resistivity. For example, a Mo-based material can be formed on a dielectric material. In some embodiments, the dielectric material includes silicon dioxide (SiO₂) (i.e., silica). Additionally or alternatively, a Mo-based material can be formed on a conductive material, such a metal or a titanium nitride (TiN) liner. In some embodiments, a Mo-based material includes molybdenum nitride (MoN). In some embodiments, a Mo-based material is formed having a thickness of less than or equal to about 10 nm. In some embodiments, the Mo-based material has a resistivity of less than or equal to about 200 μΩ·cm. In some embodiments, the resistivity of the Mo-based material ranges from about 50 μΩ·cm to about 200 μΩ·cm. Accordingly, a Mo-based material formed in accordance with embodiments described herein can have lower resistivity as compared to, e.g., tungsten nitride.

The deposition process can conformally deposit the Mo-based material on a surface. In some embodiments, the deposition process is a chemical vapor deposition (CVD) process. In some embodiments, the deposition process is an atomic layer deposition (ALD) process.

A deposition process described herein can include a number of deposition cycles. Each deposition cycle includes a reactant step to introduce a reactant, a Mo precursor step to introduce a Mo precursor, and a treatment step to introduce a treatment gas. A first purge step can be performed between the reactant step and the Mo precursor step, a second purge step can be performed between the Mo precursor step and the treatment step, and a third purge step can be performed after the treatment step. More specifically, each purge step can introduce a purge gas and has an associated purge time. A longer purge time for at least the first purge step can improve conformal deposition uniformity of the Mo-based material. The purge gas can include any suitable inert or non-reactive gas (e.g., noble gas). For example, the purge gas can include a noble gas (e.g., argon (Ar)), nitrogen gas (N₂), etc. In some embodiments, each purge step has a purge gas pulse time between about 0.5 second(s) to about 50 s. In some embodiments, each purge step has a purge gas pulse time between about 1 s to about 10 s.

In some embodiments, the number of deposition cycles ranges from about 1 cycle to about 200 cycles. In some embodiments, the number of deposition cycles ranges from about 5 cycles to about 150 cycles. In some embodiments, the number of deposition cycles ranges from about 10 cycles to about 100 cycles. In some embodiments, the deposition process is performed at a temperature that is less than or equal to about 450° C. In some embodiments, the deposition process is performed at a temperature that ranges from about 200° C. to about 450° C. In some embodiments, the deposition process is performed at a temperature that ranges from about 250° C. to about 400° C. In some embodiments, the deposition process is performed at a temperature that ranges from about 300° C. to about 375° C. In some embodiments, the deposition process is performed at a pressure that ranges from about 0.5 torr to about 300 torr. In some embodiments, the deposition process is performed at a pressure that ranges from about 2 torr to about 100 torr. In some embodiments, the deposition process is performed at a pressure that ranges from about 2 torr to about 50 torr.

More specifically, during the reactant step, a reactant is introduced to break Mo—C bonds of ligands for depositing the Mo-based material without an ex-situ reduction source (e.g., ex-situ hydrogen source), and with little to no damage to the underneath conductive layer (e.g., metal layer). The reactant step can have an associated reactant pulse time. In some embodiments, the reactant pulse time ranges from about 0.1 s to about 5 s. In some embodiments, the reactant pulse time ranges from about 0.2 s to about 1 s.

A reactant can be represented by the formula RX_{y}, where X is a halogen (e.g., chlorine (CI), bromine (Br) or iodine (I)) and y=1 or y=2. For example, if y=1, then R can be an alkyl group having a chemical formula of CₙH₂ₙ₊₁ where 1≤n≤10. Thus, in some embodiments, the reactant includes an alkyl halide (i.e., haloalkane or halogenoalkane). Generally, an alkyl halide is an alkane that includes a halogen substituent. For example, an alkyl halide can be formed from an alkane having a chemical formula CₙH₂ₙ₊₂ via halogenation (e.g., chlorination, bromination or iodination). Examples of alkyl halides include methyl halides, ethyl halides, etc.

As another example, if y=2, then R can be an alkylene group having a chemical formula of CₙH₂ₙ where 1≤n≤10. Thus, in some embodiments, the reactant includes an alkylene dihalide (i.e., haloalkene or halogenoalkene). Generally, an alkylene dihalide is an alkene that includes at a halogen substituent. For example, an alkylene dihalide can be formed from an alkene having a chemical formula CₙH₂ₙ via halogenation. Examples of alkylene dihalides include methylene dihalides, ethylene dihalides, etc.

Illustratively, if the reactant includes an alkyl halide, beta-hydride elimination can provide an in-situ reduction source to transfer hydrogen from the alkyl group or the alkylene group to Mo. This can enable Mo reduction and the ability of the alkyl group to leave the Mo surface as an alkene. In some embodiments, the reactant is an iodine-containing reactant. For example, the reactant can include an alkyl iodide or an alkylene diiodide. The general mechanism of an iodine-containing reactant is that it can decompose on a metal surface to generate a metal iodide. The iodine induces the breaking of Mo—C bonds to form Mo—I with the ligand removed from the Mo atom.

During the Mo precursor step, a Mo precursor is introduced. The Mo precursor step can have an associated Mo precursor pulse time. In some embodiments, the Mo precursor pulse time ranges from about 0.2 s to about 5 s. In some embodiments, the Mo precursor pulse time ranges from about 1 s to about 4 s. In some embodiments, the Mo precursor includes an Mo-based amide. Examples of Mo precursors include Mo(imido)₂(amino)₂, Mo(amino)₄, bis(benzene)molybdenum, bis(ethylbenzene)molybdenum, bis(trimethylsilyl)benzene-molybdenum, bis(propyl)benzene-molybdenum, bis(isopropyl)benzene-molybdenum, an alkyl substituted benzene, etc. The alkyl on benzene can be 0-5 carbon. The alkyl on benzene can be mono, di, or tri substituted benzene.

During the treatment step, a treatment gas is introduced to improve the quality of the Mo-based material. For example, the treatment gas can increase adhesion of the Mo-based material to the dielectric material (e.g., SiO₂ and/or silicon nitride). As another example, the treatment gas can improve the smoothness of the Mo-based material. For example, the smoothness of the Mo-based material can be about 0.2 nm at a thickness of about 20 nm. The treatment step can have an associated treatment gas pulse time. In some embodiments, the treatment gas pulse time ranges from about 1 s to about 150 s. In some embodiments, the treatment gas pulse time ranges from about 50 s to about 150 s. The treatment gas can include any suitable gas. In some embodiments, the treatment gas includes ammonia gas (NH₃). In some embodiments, the flow rate for the treatment gas ranges from about 10 standard cubic centimeters per minute (sccm) to about 5000 sccm. In some embodiments, the flow rate for the treatment gas ranges from about 250 sccm to about 2000 sccm. In some embodiments, the flow rate for the treatment gas ranges from about 400 sccm to about 1000 sccm.

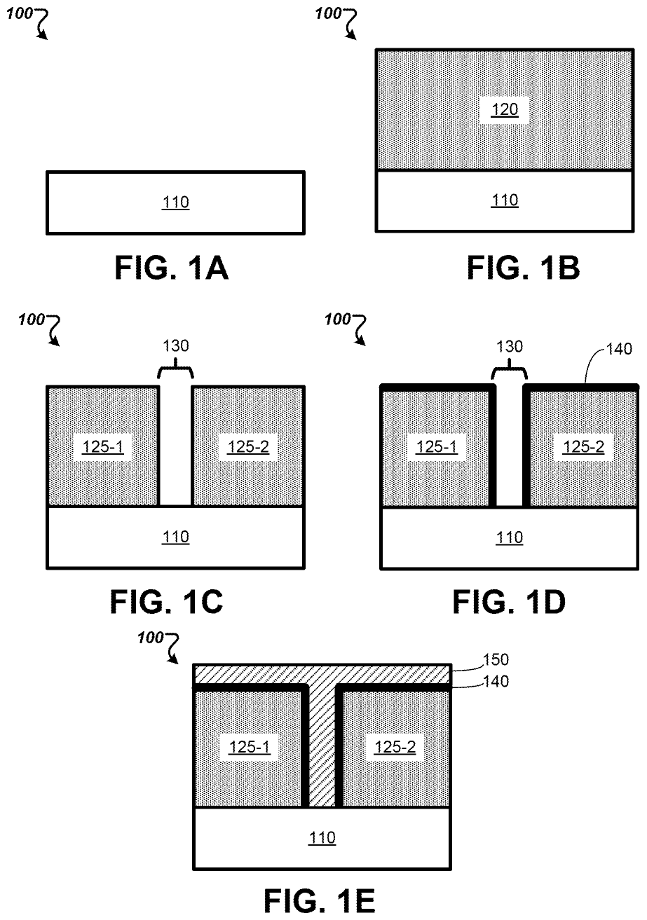

In some embodiments, a deposition process described herein is used to form liners during the fabrication of electronic devices. For example, at least one via opening can be formed within an interlevel dielectric (ILD) layer disposed on a substrate, resulting in ILD layer portions separated by the via opening. An Mo-based material can be conformally deposited as a liner along exposed surfaces of the ILD layer portions, including sidewalls of the via opening. Then, a conductive material (e.g., metal) can be formed on the liner within the via opening. Additionally or alternatively, the Mo-based material can be deposited on conductive liners (e.g., metal liners) during integration for logic or memory. Further details regarding forming Mo-based materials with improved resistivity will now be described below with reference to FIGS. 1A-5.

FIGS. 1A-1E are cross-sectional views illustrating an example method of forming an electronic device (“device”) 100, in accordance with some embodiments. As shown in FIG. 1A, a device 100 can include substrate 110. In some embodiments, substrate 110 includes a substrate layer corresponding to an initial layer of device 100 (e.g., a semiconductor wafer). For example, the substrate layer can include silicon (Si).

FIG. 1B shows the formation of ILD layer 120 on substrate 110. ILD layer 120 can include any suitable dielectric material. In some implementations, ILD layer 120 includes an oxide (e.g., a metal oxide). Examples of suitable dielectric materials include SiO₂, carbon-doped silicon oxides (e.g., SiOC, SiCOH), etc.

FIG. 1C shows the formation of at least one via opening 130 within ILD layer 120, resulting in ILD layer portions 125-1 and 125-2. At least one via opening 130 can be formed using any suitable via patterning process in accordance with embodiments described herein.

FIG. 1D shows the formation of liner 140 along exposed surfaces of ILD layer portions 125-1 and 125-2, including sidewalls of at least one via opening 130. Additionally or alternatively, liners 140 is formed on a conductive material, such a metal or a TiN liner. More specifically, liner 140 can include a Mo-based material. In some embodiments, the MO-based material is MoN. Liner 140 can be formed using a deposition process to form the Mo-based material. In some embodiments, the deposition process is an ALD process. In some embodiments, the deposition process is a CVD process. In some embodiments, liner 140 formed using the deposition process has a thickness of less than or equal to about 10 nm. In some embodiments, liner 140 formed using the deposition process has a resistivity of less than or equal to about 200 μΩ·cm. In some embodiments, the resistivity of liner 140 ranges from about 50μΩ·cm to about 200μΩ·cm.

A deposition process described herein can include a number of deposition cycles. Each deposition cycle includes a reactant step to introduce a reactant, a Mo precursor step to introduce a Mo precursor, and a treatment step to introduce a treatment gas. A first purge step can be performed between the reactant step and the Mo precursor step, a second purge step can be performed between the Mo precursor step and the treatment step, and a third purge step can be performed after the treatment step. More specifically, each purge step can introduce a purge gas and has an associated purge time. A longer purge time for at least the first purge step can improve conformal deposition uniformity of the Mo-based material. The purge gas can include any suitable inert or non-reactive gas (e.g., noble gas). For example, the purge gas can include a noble gas (e.g., Ar), N₂, etc. In some embodiments, each purge step has a purge gas pulse time between about 0.5 s to about 50 s. In some embodiments, each purge step has a purge gas pulse time between about 1 s to about 10 s.

In some embodiments, the number of deposition cycles ranges from about 1 cycle to about 200 cycles. In some embodiments, the number of deposition cycles ranges from about 5 cycles to about 150 cycles. In some embodiments, the number of deposition cycles ranges from about 10 cycles to about 100 cycles. In some embodiments, the deposition process is performed at a temperature that is less than or equal to about 450° C. In some embodiments, the deposition process is performed at a temperature that ranges from about 200° C. to about 450° C. In some embodiments, the deposition process is performed at a temperature that ranges from about 250° C. to about 400° C. In some embodiments, the deposition process is performed at a temperature that ranges from about 300° C. to about 375° C. In some embodiments, the deposition process is performed at a pressure that ranges from about 0.5 torr to about 300 torr. In some embodiments, the deposition process is performed at a pressure that ranges from about 2 torr to about 100 torr. In some embodiments, the deposition process is performed at a pressure that ranges from about 2 torr to about 50 torr.

More specifically, during the reactant step, a reactant is introduced to break Mo—C bonds of ligands for depositing the Mo-based material without an ex-situ reduction source (e.g., ex-situ hydrogen source), and with little to no damage to the underneath conductive layer (e.g., metal layer). The reactant step can have an associated reactant pulse time. In some embodiments, the reactant pulse time ranges from about 0.1 s to about 5 s. In some embodiments, the reactant pulse time ranges from about 0.2 s to about 1 s.

A reactant can be represented by the formula RX_{y}, where X is a halogen (e.g., chlorine (Cl), bromine (Br) or iodine (I)) and y=1 or y=2. For example, if y=1, then R can be an alkyl group having a chemical formula of CₙH₂ₙ₊₁ where 1≤n≤10. Thus, in some embodiments, the reactant includes an alkyl halide (i.e., haloalkane or halogenoalkane). Generally, an alkyl halide is an alkane that includes a halogen substituent. For example, an alkyl halide can be formed from an alkane having a chemical formula CₙH₂ₙ₊₂ via halogenation (e.g., chlorination, bromination or iodination). Examples of alkyl halides include methyl halides, ethyl halides, etc.

As another example, if y=2, then R can be an alkylene group having a chemical formula of CₙH₂ₙ where 1≤n≤10. Thus, in some embodiments, the reactant includes an alkylene dihalide (i.e., haloalkene or halogenoalkene). Generally, an alkylene dihalide is an alkene that includes at a halogen substituent. For example, an alkylene dihalide can be formed from an alkene having a chemical formula CₙH₂ₙ via halogenation. Examples of alkylene dihalides include methylene dihalides, ethylene dihalides, tris-halides, etc.

Illustratively, if the reactant includes an alkyl halide, beta-hydride elimination can provide an in-situ reduction source to transfer hydrogen from the alkyl group to Mo. This can enable Mo reduction and the ability of the alkyl group to leave the Mo surface as an alkene.

In some embodiments, the reactant is an iodine-containing reactant. For example, the reactant can include an alkyl iodide or an alkylene diiodide. The general mechanism of an iodine-containing reactant is that it can decompose on a metal surface to generate a metal iodide. The iodine induces the breaking of Mo—C bonds to form Mo—I with the ligand removed from the Mo atom.

During the Mo precursor step, a Mo precursor is introduced. The Mo precursor step can have an associated Mo precursor pulse time. In some embodiments, the Mo precursor pulse time ranges from about 0.2 s to about 5 s. In some embodiments, the Mo precursor pulse time ranges from about 1 s to about 4 s. In some embodiments, the Mo precursor includes an Mo-based amide. Examples of Mo precursors include Mo(imido)₂(amino)₂, Mo(amino)₄, bis(benzene)molybdenum, bis(ethylbenzene)molybdenum, bis(trimethylsilyl)benzene-molybdenum, bis(propyl)benzene-molybdenum, bis(isopropyl)benzene-molybdenum, an alkyl substituted benzene, etc. The alkyl on benzene can be 0-5 carbon. The alkyl on benzene can be mono, di, or tri substituted benzene.

During the treatment step, a treatment gas is introduced to improve the quality of the Mo-based material. For example, the treatment gas can increase adhesion of the Mo-based material to the dielectric material (e.g., SiO₂ and/or silicon nitride). As another example, the treatment gas can improve the smoothness of the Mo-based material. For example, the smoothness of the Mo-based material can be about 0.2 nm at a thickness of about 20 nm. The treatment step can have an associated treatment gas pulse time. In some embodiments, the treatment gas pulse time ranges from about 1 s to about 150 s. In some embodiments, the treatment gas pulse time ranges from about 50 s to about 150 s. The treatment gas can include any suitable gas. In some embodiments, the treatment gas includes ammonia gas (NH₃). In some embodiments, the flow rate for the treatment gas ranges from about 10 sccm to about 5000 sccm. In some embodiments, the flow rate for the treatment gas ranges from about 250 sccm to about 2000 sccm. In some embodiments, the flow rate for the treatment gas ranges from about 400 sccm to about 1000 sccm.

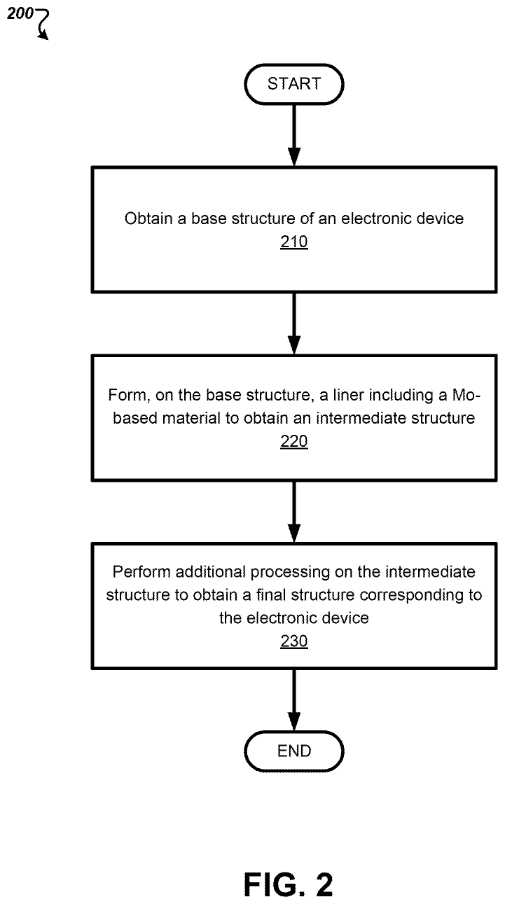

FIG. 1E shows the formation of conductive material 150 on liner 140 and within at least one via opening 130. For example, conductive material 150 can form a via within at least one via opening 130, and a conductive line formed on the via and portions of liner 140 disposed on the upper surfaces of ILD layer portions 125-1 and 125-2. Conductive material 150 can include any suitable material (e.g., metal). In some embodiments, conductive material 150 includes a transition metal. Examples of suitable materials that can be used to form conductive material 150 include Cu, W, Co, Mo, Ru, TiN, TaN, MoNₓ, etc. Further details regarding fabricating device 100 will now be described below with reference to FIG. 2.

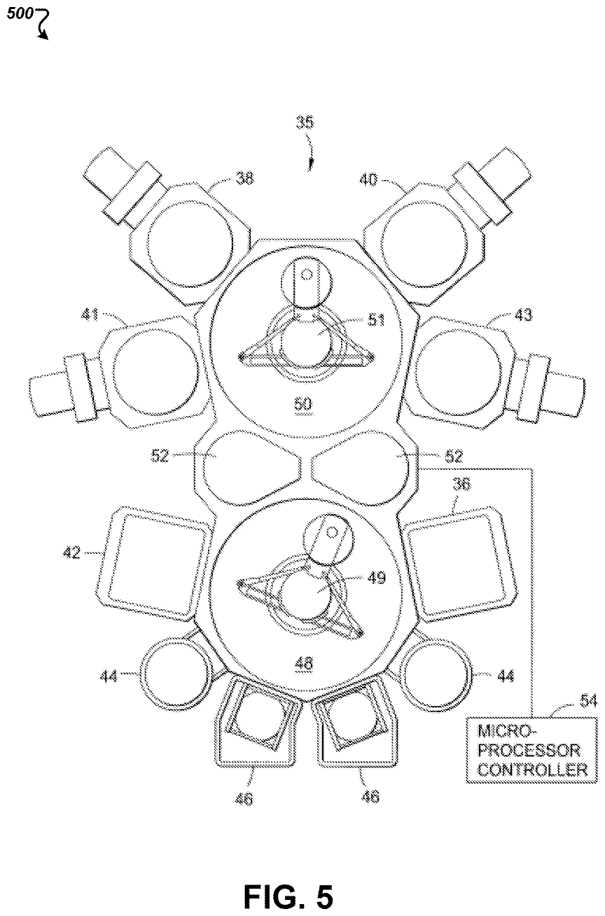

FIG. 2 depicts an example method 200 of fabricating an electronic device using area-selective deposition, in accordance with some embodiments. Method 200 can be performed within an electronic device processing system. More specifically, method 200 can be performed within one or more process chambers of the electronic device processing system. An example electronic device processing system will be described below with reference to FIG. 5.

At step 210, a base structure of an electronic device is obtained. In some embodiments, the base structure includes a substrate, an ILD layer disposed on the substrate, and at least one via opening through the ILD layer. The substrate can include at least a substrate layer (e.g., Si substrate). The substrate can further include one or more additional layers. The ILD layer can include any suitable dielectric material. In some embodiments, the ILD layer includes a silicate. For example, the ILD layer can include SiO₂.

In some embodiments, obtaining the base structure includes receiving a preformed base structure. In some embodiments, obtaining the base structure includes forming at least a portion of the base structure. For example, forming at least a portion of the base structure can include at least one of forming the ILD layer on the substrate (e.g., directly on the substrate layer or on the one or more additional layers), or forming the at least one opening through the ILD layer to form at least two ILD layer portions separated by the at least one opening.

Forming the at least one opening can include forming at least one trench within the ILD layer. For example, forming the at least one trench can include performing an etch process. If the base structure does not include a dielectric cap including an etch stop layer formed on the ILD layer, then at least one trench can be equivalent to the least one opening. Alternatively, if the base structure further includes a dielectric cap disposed on the ILD layer, then the formation of the trench using the etch process may stop at the etch stop layer. Thus, forming the at least one opening can further include performing an additional etch process (e.g., anisotropic etch process) to remove the dielectric cap. In some embodiments, the at least one opening is a via opening. In some embodiments, the at least one opening is formed by drilling through the ILD layer.

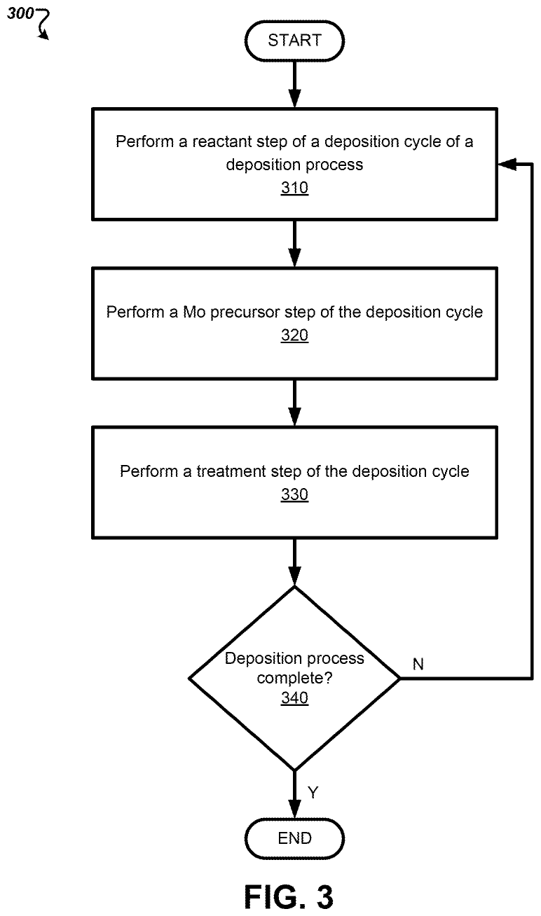

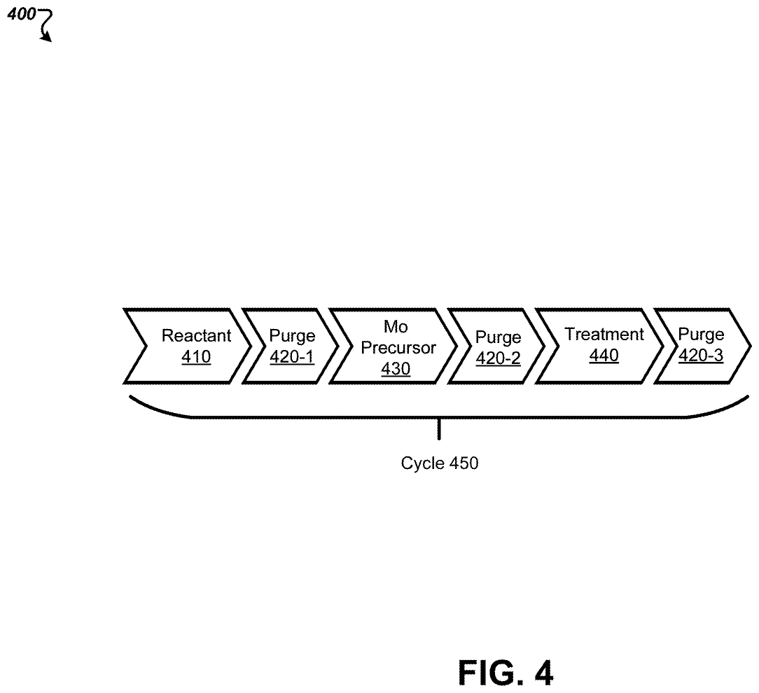

At step 220, a liner is formed on the base structure to obtain an intermediate structure. Forming the liner can include conformally depositing a liner material along exposed surfaces of the at least two ILD layer portions. For example, the liner material can be conformally deposited along sidewalls of the at least one opening, and upper surfaces of the at least two ILD layer portions. In some embodiments, the liner material includes an Mo-based material. In some embodiments, the liner is formed having a thickness of less than or equal to about 10 nm. In some embodiments, the liner is formed having a thickness of less than or equal to about 3 nm. In some embodiments, the liner has a resistivity of less than or equal to about 200 μΩ·cm. In some embodiments, the resistivity of the liner ranges from about 50 μΩ·cm to about 200 μΩ·cm. Further details regarding forming the liner on the base structure are described above with reference to FIG. 1 and will be described in further detail below with reference to FIGS. 3-4.

At step 230, additional processing is performed on the intermediate structure to obtain a final structure corresponding to the electronic device. Performing the additional processing can include forming conductive material on the liner. For example, forming conductive material on the intermediate structure can include forming a first portion of conductive material within the at least one opening, and forming a second portion of conductive material on the first portion of conductive material and the portions of the liner formed on upper surfaces of the ILD layer portions. In some embodiments, the first portion of conductive material corresponds to at least one via and the second portion of conductive material corresponds to a conductive line. The conductive material can include any suitable material(s) (e.g., metal(s)). Examples of suitable materials that can be used to form the conductive material include Cu, W, Co, Mo, Ru, TiN, TaN, MoNₓ, etc. Further details regarding steps 210-230 are described above with reference to FIGS. 1A-1E and will now be described below with reference to FIGS. 3-4.

FIG. 3 is a flow diagram illustrating example method 300 of low-temperature Mo-based material deposition, in accordance with some embodiments. For example, method 300 can be performed within one or more process chambers of an electronic device processing system. For example, the one or more process chambers can include one or more CVD chambers and/or one or more ALD chambers. In some embodiments, method 300 is performed during step 220 of FIG. 2 to form a liner including a Mo-based material on a base structure to obtain an intermediate structure during fabrication of an electronic device. For example, the liner can be formed within a trench during via formation.

At step 310, a reactant step of a deposition cycle of a deposition process is performed. The deposition process can conformally deposit the Mo-based material on a surface. In some embodiments, the surface is a surface of a dielectric material. For example, the dielectric material can be a silicate (e.g., SiO₂). In some embodiments, the dielectric material corresponds to an ILD layer. In some embodiments, the deposition process is a CVD process. In some embodiments, the deposition process is an ALD process. In some embodiments, the deposition process is performed at a temperature that ranges from about 200° C. to about 450° C. In some embodiments, the deposition process is performed at a temperature that ranges from about 250° C. to about 400° C. In some embodiments, the deposition process is performed at a temperature that ranges from about 325° C. to about 375° C. In some embodiments, the deposition process is performed at a pressure that ranges from about 0.5 torr to about 300 torr. In some embodiments, the deposition process is performed at a pressure that ranges from about 2 torr to about 100 torr. In some embodiments, the deposition process is performed at a pressure that ranges from about 2 torr to about 50 torr.

Performing the reactant step includes introducing a reactant. The reactant is introduced to break Mo—C bonds of ligands for depositing the Mo-based material without an ex-situ reduction source (e.g., ex-situ hydrogen source), and with little to no damage to the underneath conductive layer (e.g., metal layer). The reactant step can have an associated reactant pulse time. In some embodiments, the reactant pulse time ranges from about 0.1 s to about 5 s. In some embodiments, the reactant pulse time ranges from about 0.2 s to about 1 s. Examples of reactants are described above with reference to FIGS. 1-2.

In some embodiments, performing the reactant step further includes performing a first purge step after introducing the reactant. More specifically, the first purge step can introduce a first purge gas. The first purge gas can include any suitable inert or non-reactive gas (e.g., noble gas). For example, the first purge gas can include Ar. In some embodiments, the first purge step has a purge gas pulse time between about 0.5 s to about 50 s. In some embodiments, the first purge step has a purge gas pulse time between about 1 s to about 10 s. A longer purge time for the first purge step can improve conformal deposition uniformity of the Mo-based material.

At step 320, a Mo precursor step of the deposition cycle is performed. Performing the Mo precursor step includes introducing a Mo precursor. The Mo precursor step can have an associated Mo precursor pulse time. In some embodiments, the Mo precursor pulse time ranges from about 0.2 s to about 5 s. In some embodiments, the Mo precursor pulse time ranges from about 1 s to about 4 s. The Mo precursor can include any suitable precursor. In some embodiments, the Mo precursor includes an Mo-based amide. Examples of Mo precursors include Mo(imido)₂(amino)₂, Mo(amino)₄, bis(benzene)molybdenum, bis(ethylbenzene)molybdenum, bis(trimethylsilyl)benzene-molybdenum, bis(propyl)benzene-molybdenum, bis(isopropyl)benzene-molybdenum, etc.

In some embodiments, performing the Mo precursor step further includes performing a second purge step after introducing the Mo precursor. More specifically, the second purge step can introduce a second purge gas. The second purge gas can include any suitable inert or non-reactive gas (e.g., noble gas). For example, the second purge gas can include Ar. In some embodiments, the second purge step has a purge gas pulse time between about 0.5 s to about 50 s. In some embodiments, the second purge step has a purge gas pulse time between about 1 s to about 10 s.

At step 330, a treatment step of the deposition cycle is performed. Performing the treatment step includes introducing a treatment gas. The treatment step can be performed to improve the quality of the Mo-based material. For example, the treatment gas can increase adhesion of the Mo-based material to the dielectric material (e.g., SiO₂ and/or silicon nitride). As another example, the treatment gas can improve the smoothness of the Mo-based material. For example, the smoothness of the Mo-based material can be about 0.2 nm at a thickness of about 20 nm. The treatment step can have an associated treatment gas pulse time. In some embodiments, the treatment gas pulse time ranges from about 1 s to about 150 s. In some embodiments, the treatment gas pulse time ranges from about 50 s to about 150 s. The treatment gas can include any suitable gas. In some embodiments, the treatment gas includes NH₃. In some embodiments, the flow rate for the treatment gas ranges from about 10 sccm to about 5000 sccm. In some embodiments, the flow rate for the treatment gas ranges from about 250 sccm to about 2000 sccm. In some embodiments, the flow rate for the treatment gas ranges from about 400 sccm to about 1000 sccm.

In some embodiments, performing the treatment step further includes performing a third purge step after introducing the Mo precursor. More specifically, the third purge step can introduce a third purge gas. The third purge gas can include any suitable inert or non-reactive gas (e.g., noble gas). For example, the third purge gas can include Ar. In some embodiments, the third purge step has a purge gas pulse time between about 0.5 s to about 50 s. In some embodiments, the third purge step has a purge gas pulse time between about 1 s to about 10 s.

At step 340, it is determined whether the deposition process is complete. For example, determining whether the deposition process is complete can include determining whether the deposition cycle is a final deposition cycle of the deposition process. If the deposition process is not complete, then the process can revert back to step 310 to initiate another deposition cycle and perform the reactant step. Otherwise, if the deposition process is complete, then the deposition process to form the Mo-based material is complete (e.g., Mo-based liner).

The deposition process can have any suitable number of cycles. In some embodiments, the number of cycles ranges from about 1 cycle to about 200 cycles. In some embodiments, the number of cycles ranges from about 5 cycles to about 150 cycles. In some embodiments, the number of cycles ranges from about 10 cycles to about 100 cycles. In some embodiments, the Mo-based material is formed having a thickness of less than or equal to about 10 nm. In some embodiments, the Mo-based material has a resistivity of less than or equal to about 200 μΩ·cm. In some embodiments, the resistivity of the Mo-based material ranges from about 50 μΩ·cm to about 200 μΩ·cm. Further details regarding steps 310-340 are described above with reference to FIGS. 1A-2 and will now be described below with reference to FIG. 4.

FIG. 4 is a diagram 400 illustrating example method of low-temperature molybdenum (Mo)-based material deposition, in accordance with some embodiments. The method includes reactant step 410 to introduce a reactant, purge step 420-1 following reactant step 410, Mo precursor step 430 to introduce a Mo precursor, purge step 420-2 following Mo precursor step 430, treatment step 440 to introduce a treatment gas, and purge step 420-3 following treatment step 440. Steps 410-440 collective form a deposition cycle (“cycle”) 450 of a deposition process to form a Mo-based material with improved resistivity. In some embodiments, the deposition process is an ALD process. The deposition process can have any suitable number of cycles. In some embodiments, the number of cycles ranges from about 1 cycle to about 200 cycles. In some embodiments, the number of cycles ranges from about 5 cycles to about 150 cycles. In some embodiments, the number of cycles ranges from about 10 cycles to about 100 cycles. Further details regarding steps 410-440 are described above with reference to FIGS. 1-3.

FIG. 5 is a diagram of a top-down view of a multi-chamber processing platform system (“system”) 35, in accordance with some embodiments. System 35 can be used to fabricate electronic devices such as device 100 described above with reference to FIG. 1 and/or perform methods of low-temperature Mo-based material deposition (e.g., to fabricate electronic devices), such as one or more of methods 200-400 described above with reference to FIGS. 2-4. Deposition processes may be performed in system 500, which can have at least one ALD chamber, at least one CVD chamber, at least one physical vapor deposition (PVD) chamber, or at least one annealing chamber disposed thereon.

System 35 can include at least two transfer chambers 48, 50, at least two transfer robots 49, 51, disposed within transfer chambers 48, 50 respectfully, and a plurality of processing chambers 36, 38, 40, 41, 42 and 43. Transfer chamber 48 and transfer chamber 50 can be separated by pass-through chambers 52, which may comprise cool-down or pre-heating chambers. Pass-through chambers 52 can also be pumped down or ventilated during substrate handling when transfer chamber 48 and the transfer chamber 50 operate at different pressures. For example, transfer chamber 48 may operate at a pressure within a range from about 100 milliTorr to about 5 Torr, such as about 400 milliTorr, and transfer chamber 50 may operate at a pressure within a range from about 1×10⁻⁵ Torr to about 1×10⁻⁸ Torr, such as about 1×10⁻⁷ Torr. Processing platform system 35 can be controlled using microprocessor controller 54.

Transfer chamber 48 is coupled with at least two degas chambers 44, at least two load lock chambers 46, preclean chamber 42 and chamber 36, such as a CVD processing chamber or an ALD processing chamber. Substrates can be sequentially degassed and cleaned in degas chambers 44 and the preclean chamber 42, respectively. Transfer robot 49 can move a substrate between degas chambers 44 and preclean chamber 42. The substrate may then be transferred into chamber 36 for deposition of a material thereon.

Transfer chamber 50 is coupled to a cluster of processing chambers 38, 40, 41, and 43. In one example, chambers 38 and 40 can include a CVD chamber and/or an ALD chamber for depositing materials. A CVD chamber can be adapted to deposit materials using CVD techniques or ALD techniques. Chambers 41 and 43 can include a rapid thermal annealing (RTA) chamber and/or a rapid thermal process (RTP) chamber, that can anneal substrates at low or extremely low pressures. Alternatively, chambers 41 and 43 be deposition chambers capable of performing one or more of CVD, ALD, annealing, in situ deposition, etc. A substrate can be moved from transfer chamber 48 into transfer chamber 50 via pass-through chambers 52. Thereafter, transfer robot 51 can move the substrate between one or more of the processing chambers 38, 40, 41, and 43 for material deposition and annealing as needed for processing.

While not shown, a plurality of vacuum pumps is disposed in fluid communication with each transfer chamber and each of the processing chambers to independently regulate pressures in the respective chambers. The pumps may establish a vacuum gradient of increasing pressure across the apparatus from the load lock chamber to the processing chambers. Additionally, one or more etch chambers can be coupled to processing platform system 35 or in a separate processing system for etching the substrate surface. For example, the one or more etch chambers can include a dry etch chamber (e.g., plasma etch chamber) and/or a wet etch chamber.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
performing a reactant step of a deposition cycle of a deposition process to form a molybdenum (Mo)-based material, wherein performing the reactant step comprises introducing a reactant;
performing a Mo precursor step of the deposition cycle, wherein performing the Mo precursor step comprises introducing a Mo precursor; and
performing a treatment step of the deposition cycle, wherein performing the treatment step comprises introducing a treatment gas;
wherein the deposition process is performed at a temperature that is less than or equal to about 450° C.

2. The method of claim 1, wherein the reactant comprises an alkyl halide.

3. The method of claim 2, wherein the reactant comprises an alkylene dihalide.

4. The method of claim 1, wherein the reactant comprises iodine.

5. The method of claim 1, wherein Mo precursor comprises a Mo-based amide.

6. The method of claim 1, wherein the Mo precursor comprises at least one of: Mo(imido)₂(amino)₂, Mo(amino)₄, bis(benzene)molybdenum, bis(ethylbenzene)molybdenum, bis(trimethylsilyl)benzene-molybdenum, bis(propyl)benzene-molybdenum, or bis(isopropyl)benzene-molybdenum.

7. The method of claim 1, wherein the treatment gas comprises ammonia gas.

8. The method of claim 1, wherein the deposition process is performed at a temperature that ranges from about 250° C. to about 400° C.

9. The method of claim 1, wherein the deposition process is performed at a temperature that ranges from about 300° C. to about 375° C.

10. The method of claim 1, wherein the reactant step has an associated reactant pulse time that ranges from about 0.1 second to about 5 seconds.

11. The method of claim 1, wherein the Mo precursor step has an associated Mo precursor pulse time that ranges from about 1 second to about 5 seconds.

12. The method of claim 1, wherein the treatment step has an associated treatment gas pulse time that ranges from about 50 seconds to about 150 seconds.

13. The method of claim 1, wherein the treatment gas has an associated flow rate that ranges from about 400 standard cubic centimeters per minute (sccm) to about 1000 sccm.

14. The method of claim 1, wherein:
performing the reactant step further comprises performing a first purge step after introducing the reactant;
performing the Mo precursor step further comprises performing a second purge step after introducing the Mo precursor; and
performing the treatment step further comprises performing a third purge step after introducing the treatment gas.

15. The method of claim 14, wherein the first purge step, the second purge step and the third purge step each have an associated purge gas pulse time that ranges between about 1 second to about 10 seconds.

16. The method of claim 1, wherein the Mo-based material is formed as a liner along a trench.

17. The method of claim 1, wherein the Mo-based material comprises molybdenum nitride (MoN).

18. A device comprising:
a trench; and
a liner comprising a Mo-based material formed along the trench, wherein the Mo-based material has a resistivity less than or equal to about 200 microohm-centimeters (μΩ·cm).

19. The device of claim 18, wherein the Mo-based material comprises molybdenum nitride (MoN).

20. The device of claim 18, wherein the device is associated with a technology node of less than about 3 nanometers.
